(19) United States
(12) Patent Application Publication
(10) Pub. No.: US 2024/0107723 A1
(43) Pub. Date: Mar. 28, 2024

(54) Thermal Protection for Helmet Mounted Visual Communication and Navigation System

(71) Applicant: Qwake Technologies, Inc., San Francisco, CA (US)

(72) Inventors: Phil Houdek, San Jose, CA (US); Mike Ralston, Mountain View, CA (US); Omer Haciomeroglu, Austin, TX (US); Sam Cossman, Austin, TX (US)

(73) Assignee: Qwake Technologies, Inc., San Francisco, CA (US)

(21) Appl. No.: 18/371,504

(22) Filed: Sep. 22, 2023

Related U.S. Application Data
(60) Provisional application No. 63/409,204, filed on Sep. 22, 2022.

(51) Int. Cl. H05K 7/20; G02B 27/01

(52) U.S. Cl. CPC H05K 7/20963; G02B 27/017; H05K 7/2039

(57) ABSTRACT

The technology described herein relates to thermal protection for a helmet mounted visual communication and navigation system. A thermal protection system may include a vision module heat sink configured to store heat dissipated from electronic components of a vision module, a compute module heat sink configured to store heat dissipated from electronic components of a compute module, and a compute module heat spreader near an electronic component of the compute module, wherein both the vision module heat sink and the compute module heat sink comprise a heat sink core at least partially filled with a phase change material. The system also may include a gasket configured to create a seal around an edge of a heat sink shell and a thermal sensor to provide data to be used to determine a remaining thermal reserve. The system also may include a cable housing configured to protect a cable from exterior heat.

### CROSS-REFERENCE TO RELATED APPLICATIONS

This application claims priority to U.S. Provisional Patent Application No. 63/409,204 entitled “Thermal Protection for Helmet Mounted Navigation and Communications System,” filed Sep. 22, 2022, the contents of which are hereby incorporated by reference in their entirety.

### FIELD OF INVENTION

The present invention relates to fire fighting, military, and safety gear. More particularly, the invention is directed to a wearable helmet mounted visual communication and navigation system.

### BACKGROUND OF INVENTION

Fire fighting, life safety situations, military, law enforcement, emergency rescues, public safety and other missions and exercises frequently create a need for emergency response personnel and other critical workers to be able to see in the dark and through smoke. In such situations, navigation and communications gear that can provide emergency response and critical worker personnel with more information to safely and quickly operate is essential. Conventional solutions include handheld thermal cameras, handheld radios, shoulder microphones, face mask mounted microphones and radios, flashlights, and physical tags. However, handheld implementations are cumbersome in emergency situations, and occupy hands that are needed for other tasks. Handheld implementations also often operate at a relatively larger distance from a user's eye, which increases the likelihood that smoke will obscure the visual path between the user's and the display screen.

Problems with existing solutions for mounting thermal cameras, or other navigation and communications gear, onto a user's wearable safety helmet or other wearable safety gear (i.e., onto a part of a uniform or other body-worn gear) includes unevenly weighing down a front or side of helmets and uniforms, snag hazards, and, when mounted onto other wearable safety gear, lack of ability to track a user's head motion.

Therefore, a balanced helmet mounted (i.e., hands free) visual communication and navigation system is desirable.

### BRIEF SUMMARY

The present disclosure provides for a thermal protection system for a helmet mounted visual communication and navigation system. A thermal protection system may include: a vision module heat sink configured to store heat dissipated from one or more electronic components of a vision module; a compute module heat sink configured to store heat dissipated from one or more electronic components of a compute module; and a compute module heat spreader coupled to the compute module heat sink and an electronic component of the compute module; wherein each of the vision module heat sink and the compute module heat sink comprises a heat sink core at least partially filled with a phase change material.

In some examples, the compute module comprises a compute module housing and a printed circuit board assembly (PCBA). In some examples, the compute module housing and the PCBA each comprise two larger regions and a smaller region between the two larger regions. In some examples, the compute module heat sink comprises a pair of compute module heat sinks distributed among the two larger regions of the compute module housing. In some examples, the one or more electronic components of the compute module are placed on one or both of the two larger regions of the PCBA near at least one of the pari of compute module heat sinks. In some examples, the compute module is coupled to a user's helmet such that it sits under a back brim of the user's helmet and wraps around a back portion of a user's head. In some examples, the vision module comprises a vision module housing and the compute module comprises a compute module housing, one or both of the vision module housing and the compute module housing comprising a reflective coating.

In some examples, the system also includes one or both of a compute module insulation and a vision module insulation. In some examples, one or both the compute module insulation and the vision module insulation comprise a foam or foam-like material having a low thermal conductivity. In some examples, an outer surface of one or both of the compute module insulation and the vision module insulation comprises a plurality of grooves. In some examples, an outer surface of one or both of the compute module insulation and the vision module insulation comprises a smooth surface. In some examples, one or both of the vision module heat sink and the compute module heat sink comprises a heat sink shell comprised of a material having a high operating temperature. In some examples, the material is glass filled engineering injection molding resin.

In some examples, the system also includes a gasket configured to create a seal around an edge of the heat sink shell, the gasket configured to seal the phase change material in a volume between the heat sink shell and the heat sink core. In some examples, one or both of the vision module heat sink and the compute module heat sink comprises a volume of the phase change material, the volume tuned to an amount of heat dissipating from the one or more electronic components of the vision module and the one or more electronic components of the compute module, respectively. In some examples, the compute module heat sink comprises a plurality of fins bonded to the heat spreader, the heat spreader further configured to provide stiffness and support to the one or more electronic components of a compute module. In some examples, the heat spreader comprises a sealing fastener, wherein removal of the sealing fastener exposes an opening configured for adding the phase change material to an internal volume of the heat sink.

In some examples, the vision module heat sink comprises a mounting feature for one or more components of the vision module. In some examples, the mounting feature comprises a mounting boss and a fastener. In some examples, the mounting feature isolates the vision module heat sink and reduces a thermally conductive physical interface between the one or more electronic components of the vision module and an outside environment. In some examples, the heat sink core comprises aluminum.

In some examples, the system also includes a cable housing comprising heat resistant material configured to protect a cable from exterior heat. In some examples, the system also includes one or more thermal sensors submerged in the phase change material, the one or more thermal sensors configured to provide data being used to determine a remaining thermal reserve.

### BRIEF DESCRIPTION OF THE DRAWINGS

Various non-limiting and non-exhaustive aspects and features of the present disclosure are described hereinbelow with references to the drawings, wherein:

FIGS. 1A-1B are a side and a perspective view of an exemplary helmet with a balanced helmet mounted visual communication and navigation system, in accordance with one or more embodiments.

FIG. 2 is an exploded view of an exemplary helmet with a balanced helmet mounted visual communication and navigation system, in accordance with one or more embodiments.

FIG. 3 is a perspective view of an exemplary helmet with a balanced helmet mounted visual communication and navigation system, in accordance with one or more embodiments.

FIG. 4 is another perspective view of an exemplary helmet with a balanced helmet mounted visual communication and navigation system, in accordance with one or more embodiments.

FIG. 5 is an exploded view of an internal core subassembly in an exemplary compute module, in accordance with one or more embodiments.

FIG. 6 is an exploded view of another internal core subassembly in an exemplary compute module, in accordance with one or more embodiments.

FIG. 7 is an exploded view of an exemplary vision module, in accordance with one or more embodiments.

FIGS. 8A-8B are a top and cross-section views of an exemplary compute module, in accordance with one or more embodiments.

FIG. 9 is an exploded view of an exemplary compute module, in accordance with one or more embodiments.

FIGS. 10A-10C are isolated cut, cross-section, and side views, respectively, of an exemplary compute module bottom insulation, in accordance with one or more embodiments.

FIGS. 11A-11C are top views of an exemplary outer surface of a compute module insulation, in accordance with one or more embodiments.

FIG. 12 is a cross-section view of an exemplary temperature sensing system, in accordance with one or more embodiments.

FIGS. 13A-13B are exploded views of an exemplary compute module heat sink and stiffener, in accordance with one or more embodiments.

FIG. 14 is perspective view of an exemplary compute module heat sink and stiffener as assembled, in accordance with one or more embodiments.

FIGS. 15A-15B are top and cross-section views, respectively, of an exemplary compute module heat sink, in accordance with one or more embodiments.

FIGS. 16A-16B are perspective front and back views of a vision module heat sink, in accordance with one or more embodiments.

FIG. 17 is an exploded view of a vision module heat sink, in accordance with one or more embodiments.

Like reference numbers and designations in the various drawings indicate like elements. Skilled artisans will appreciate that elements in the Figures are illustrated for simplicity and clarity, and have not necessarily been drawn to scale, for example, with the dimensions of some of the elements in the figures exaggerated relative to other elements to help to improve understanding of various embodiments. Common, well-understood elements that are useful or necessary in a commercially feasible embodiment are often not depicted in order to facilitate a less obstructed view of these various embodiments.

### DETAILED DESCRIPTION

The invention is directed to a balanced helmet mounted (i.e., hands free) visual communication and navigation system. A helmet mounted visual communication and navigation system may include a vision module coupled to a front portion (e.g., a front surface) of a helmet, a compute module coupled to a rear (i.e., back) surface of the helmet, a cable that connects the vision module and the compute module, a first attachment element configured to removably couple the vision module to the helmet, a second attachment element configured to removably couple the compute module to the helmet. The vision and compute modules may provide navigation functions (e.g., using lights, laser, camera, heads up display (HUD), navigation user interface, processing and compute for control thereof) for the balanced helmet mounted visual communication and navigation system. The vision and compute modules also may provide communication functions (e.g., using lights, laser, user control buttons). The first attachment element may comprise mating features to the helmet's contours on a first side and to the vision module on a second side. The second attachment element may comprise mating features to the helmet's contours on a first side and to the compute module on a second side. The first and second attachment elements allow the vision module and compute module, respectively, to be attached to, and detached from, the helmet. In some examples, the vision module and compute module may be coupled to various different (e.g., varying designs) and unique (e.g., separate, user-specific) helmets. For example, the shape, pattern, number of adhesive mount pads, and other configurations, on a helmet-facing portion of a compute module attachment may be varied to match different types of helmets, while keeping shape and coupling elements of a compute module-facing portion of a compute module attachment matching that of a given compute module. For example, the module-facing side of a second attachment may be contoured to fit a compute module surface, this module-facing contour may be maintained across different types of helmets, while the helmet-facing side may be contoured to fit an inner helmet surface of the back portion of a helmet and may be varied across different types of helmets. This modular design allows for a given compute module to be removably coupled to different types of helmets. Similarly, the shape, pattern, helmet-coupling elements, and other configurations, on a helmet-facing portion of a vision module attachment may be varied to match different types of helmets, while keeping shape and coupling elements of a vision module-facing portion of a vision module attachment matching that of a given vision module. This modular design allows for a given compute module to be removably coupled to different types of helmets.

A visual communication and navigation system may be coupled to parts of a safety helmet and may comprise built-in thermal camera and other sensors, a heads up display to view enhanced visual information comprising both raw and processed sensor data from said thermal camera and other sensors. The thermal camera and other sensors may include situational awareness sensors (e.g., cameras (e.g., a thermal imaging camera (TIC), a radiometric thermal camera, a drone camera), a spectrometer, a photosensor, a magnetometer, a seismometer, a gas detector, a chemical sensor, a radiological sensor, a voltage detector, a flow sensor, a scale, a thermometer, a pressure sensor, an acoustic sensor (e.g., selective active noise cancellation to facilitate radio communication), an inertial measurement unit, a GPS sensor, a speedometer, a pedometer, an accelerometer, an altimeter, a barometer, an attitude indicator, a depth gauge, a compass (e.g., fluxgate compass), a gyroscope, and the like) and biometric sensors to measure (e.g., monitor) health conditions and status of a user (e.g., a heart rate sensor, a blood pressure monitor, a glucose sensor, an electrocardiogram (e.g., EKG or ECG) sensor, an electroencephalogram (EEG) sensor, an electromyography (EMG) sensor, a respiration sensor, a neurological sensor, and the like). In some examples, the visual communication and navigation system also may include a pointing laser (e.g., for depth measurement in an extreme environment with low visibility, otherwise to help a user navigate, as well as a visual indication to other personnel of the user's presence and approximate location) and other tools.

The visual communication and navigation system may be helmet mounted such that the visual and other sensors can track a user's head motion and approximates where the user is looking so that the heads up display includes the user's current point of view. For example, the HUD may be configured to display a representation of a user's environment from the user's point of view. The HUD display may face the user within the user's field of vision. Such a helmet mounted system also reduces snag hazard and allows for integration with streamlined emergency personnel and critical worker procedures and workflows.

The visual communication and navigation system may comprise two or more modules to be coupled at different locations on a helmet, the two or more modules configured to minimize the added moment of inertia to reduce a user's perceived mass of the system. The two or more modules may be strategically placed to wrap around inner and outer surfaces of a helmet largely using available, unused space within and around a helmet. The two or more modules may be configured to implement a cognitive load reducing platform comprising a plurality of sensors, a compute subassembly (e.g., processor, memory) configured to execute a cognitive enhancement engine (e.g., software-based engine configured to process sensor data into enhanced characterization data configured to provide contextual and physiological visual, auditory, and/or haptic cues and information), and an output device (e.g., HUD, other visual display, headphones, earbuds, other auditory output devices, haptic device, and the like).

The two or more modules may include a vision module comprising a heads up display (HUD) combiner subassembly, one or more user control buttons, a laser, an indicator light, a camera and other sensors, and a cable connection interface, or a sub-combination thereof, as described in more detail herein. The two or more modules also may include a compute module comprising at an internal core subassembly including least some of the electronics for operation of the visual communication and navigation system (e.g., a circuit board assembly (e.g., CPU, other PCB or processing unit), memory, an antenna, and other computing components), heat management elements (e.g., heat reservoirs and heat spreaders), power module (e.g., battery module, charging module, power cord port, and other means of providing power to operate the visual communication and navigation system), or a sub-combination thereof, as described in more detail herein. In some examples, the compute module also may include a sensor (e.g., NFC tag reader, RFID tag reader, camera, scanner, combined NFC-RFID antenna, and the like). In some examples, the compute module also may comprise one or more lights as part of a visual communications system (e.g., controlled using manual inputs (e.g., user control buttons) and passive inputs (e.g., sensor data, communications data, and the like)).

In some examples, the visual communication and navigation system may include thermal protection features to protect electronic parts and systems, including heat resistant materials, insulation, heat reservoirs (e.g., heat sinks comprising phase change material to store heat dissipated from electronic parts and systems), heat spreaders, and the like.

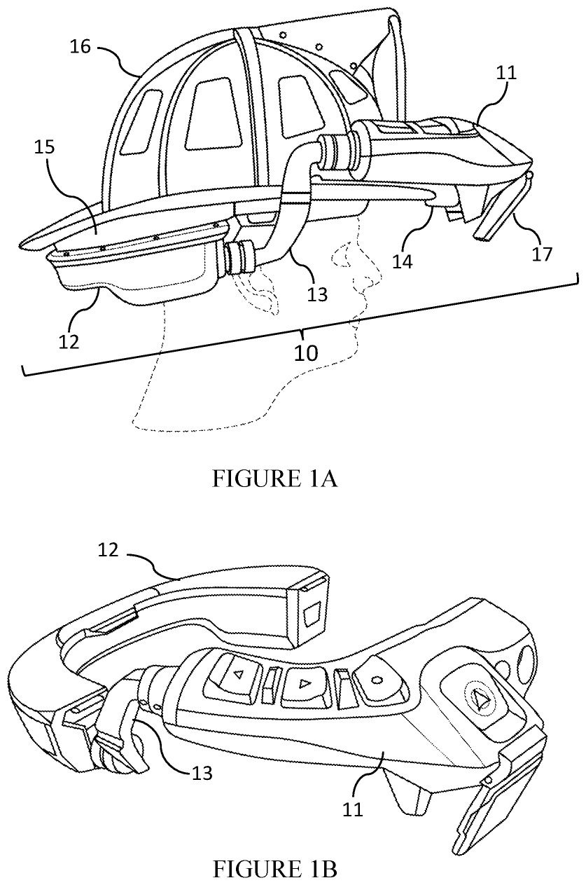

FIGS. 1A-1B are a side and a perspective view of an exemplary helmet with a balanced helmet mounted visual communication and navigation system, in accordance with one or more embodiments. A visual communication and navigation system 10 may be removably coupled (e.g., attached and detached using attachments 14-15) to helmet 16. Vision module 11 and compute module 12 are shown connected using cable 13 (e.g., comprising a system cable, data cable, and/or other cables and wires). In some examples, vision module 11 attaches and detaches to vision module attachment 14 without tools, and compute module 12 similarly attaches and detaches to compute module attachment 15 without tools. Vision module attachment 14 and compute module attachment 15 may be more permanently coupled (e.g., adhesively bonded, mechanically attached) to helmet 16. In some examples, vision module attachment 14 may be coupled to a top surface of a front brim of helmet 16, as shown. In some examples, compute module attachment 15 may be coupled to a bottom surface of a back portion (e.g., brim) of helmet 16, as shown. Vision module 11 may include heads up display (HUD) combiner subassembly 17, which is shown in a partially open position wherein the display portion is flipped partially down (e.g., a position wherein the display is viewable by a user). As shown in FIG. 1B, a HUD may flip down into an open position to occupy a portion of a user's field of view. Said HUD may flip up into a closed position when not in use. In some examples, the HUD may be formed using materials able to withstand high heat, smoke-filled, and other extreme conditions. In some examples, the HUD may comprise a plurality of layers, including a world facing shell, a glass or plastic mirror or partial mirror, and a user facing shell, the world facing shell and user facing shell bonded, or otherwise secured, along their perimeter edge to create a sealed volume enclosing the mirror within. In some examples, the world facing shell and user facing shell may comprise a largely clear material configured to enable viewing of the glass display (e.g., a combiner glass configured to display a graphical user interface) and may be coated with hydrophilic material to minimize fogging and optical distortion from moisture (e.g., encourage water sheeting). In some examples, the world facing shell and user facing shell also may be treated with a coating, or may comprise a material, that is heat and/or debris resistant.

In some examples, vision module 11 may comprise a HUD combiner subassembly, one or more user control buttons, a laser, an indicator light, a camera and other sensors, and a cable connection interface, or a sub-combination thereof, as described in more detail herein. In some examples, compute module 12 may comprise an internal core subassembly including least some of the electronics for operation of the visual communication and navigation system (e.g., a circuit board assembly (e.g., CPU, other PCB or processing unit), memory, an antenna, and other computing components), heat management elements (e.g., heat reservoirs and heat spreaders), power module (e.g., battery module, charging module, power cord port, and other means of providing power to operate the visual communication and navigation system), or a sub-combination thereof, as described in more detail herein. In some examples, the compute module also may include a sensor (e.g., NFC tag reader, RFID tag reader, camera, scanner, combined NFC-RFID antenna, and the like). In some examples, the compute module also may comprise one or more lights as part of a visual communications system (e.g., controlled using manual inputs (e.g., user control buttons) and passive inputs (e.g., sensor data, communications data, and the like)).

Visual communication and navigation system 10 may comprise a thermal protection system including heat resistant materials, insulation, heat reservoirs (e.g., heat sinks comprising phase change material configured to store heat dissipated from electronic parts and systems), heat spreaders, as described herein.

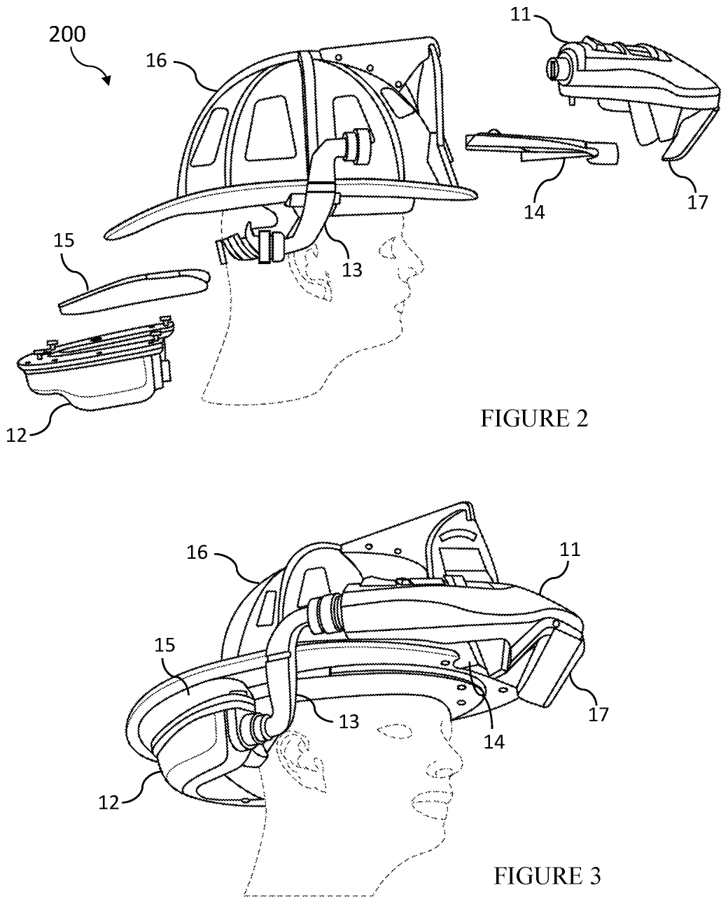

FIG. 2 is an exploded view of an exemplary helmet with a balanced helmet mounted visual communication and navigation system, in accordance with one or more embodiments. All like-numbered elements in FIG. 2 are the same or similar to their corresponding elements in other figures. View 200 includes the same or similar vision module 11, compute module 12, cable 13, vision module attachment 14, compute module attachment 15, and helmet 16. In some examples, cable 13 may have one end removably coupled to vision module 11 and another end removably coupled to compute module 12. In some examples, cable 13 may comprise a housing, one or more electrical wires and/or light cables (e.g., coaxial, fiber optic, data, ethernet, twisted wire pairs, audio, HDMI, VGA, other video, and the like) housed (e.g., encased) within the housing, and two or more connector ends, each configured to physically, electrically, and communicatively connect to a module (e.g., vision module 11, compute module 12, and the like). In some examples, cable 13's housing may comprise heat resistant material. In some examples, cable 13's housing also may include insulation or other thermal protective features to protect electrical and/or light cables housed within from overheating. In other examples, cable 13's housing may be provided with a shape configured to approximately conform to a side contour of helmet 16 such that cable 13's housing does not jut out from helmet 16, thereby avoiding being a snag hazard (e.g., opportunity for snagging on other objects and surfaces with which the helmet, cable, and other parts of the helmet mounted visual communication and navigation system may contact). For example, as shown, said housing may be flatter left to right with a slight curve (e.g., a C-curve) so that one end connects with vision module 11 at least partly over the brim of helmet 16 and another end connects with compute module 12 at least partly under the brim of helmet 16. Also, as shown, said housing may be wider front to back to accommodate the volume of multiple cables and/or allow for cable angles due to tension or stiffness of materials. In some examples, said housing may have a slight double curve (e.g., an S-curve) in one dimension to reach corresponding connectors on two or more various modules. In other examples, cable 13's housing may comprise a flexible material able to take on any shape necessary to connect two or more modules and house any necessary electrical and light cables. In some examples, each end of cable 13 may comprise an interface for removably coupling to a corresponding connector on a module, mechanically (e.g., screwing or popping on and off) and electrically (e.g., male-female electrical, data, audio interfaces).

FIG. 3 is a perspective view of an exemplary helmet with a balanced helmet mounted visual communication and navigation system, in accordance with one or more embodiments. All like-numbered elements in FIG. 3 are the same or similar to their corresponding elements in other figures.

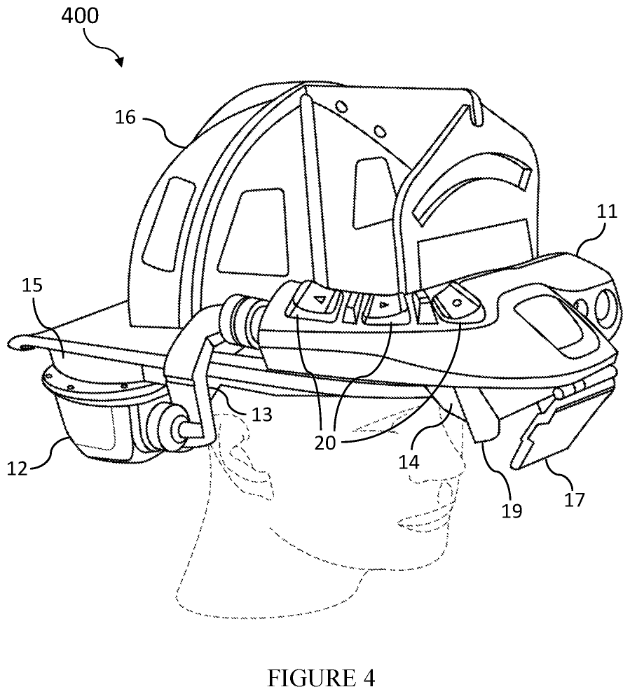

FIG. 4 is another perspective view of an exemplary helmet with a balanced helmet mounted visual communication and navigation system, in accordance with one or more embodiments. All like-numbered elements in FIG. 4 are the same or similar to their corresponding elements in other figures. View 400 provides a top down perspective view that further shows an aperture 18, bumper(s) 19, and user control button(s) 20. In some examples, aperture 18 may be configured to provide an opening through which a thermal camera or other sensor may receive light and other sensory input. In some examples, aperture 18 may be covered with glass (e.g., germanium glass) or other material able to pass infrared light, for example, while providing an enclosure to maintain an ingress protected seal. In some examples, additional apertures may be provided on vision module 11 (e.g., for additional sensors, a laser, and the like).

In some examples, one or more bumper(s) 19 may be provided, for example, protruding down on either side of the HUD combiner subassembly 17 to protect the HUD combiner subassembly 17 from damage (e.g., from flying or falling debris, contact with obstacles, impact from normal wear and tear, and other impact from contact with surfaces and objects). In some examples, bumper(s) 19 may comprise elastomeric material.

In some examples, user control buttons 20 may control elements of a visual communications system, including one, or a combination, of a laser, lights (e.g., a rear communication (e.g., tail and/or brake) light facing backward on compute module 12, other lights on any module coupled to helmet 16 and/or coupled using cable 13), and any other visual communication unit or element on a helmet mounted visual communication and navigation system.

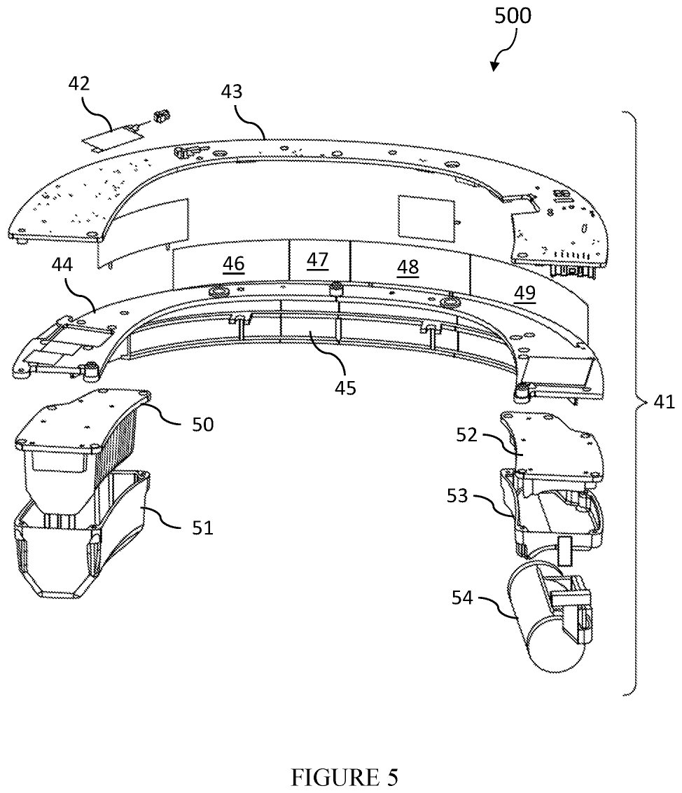

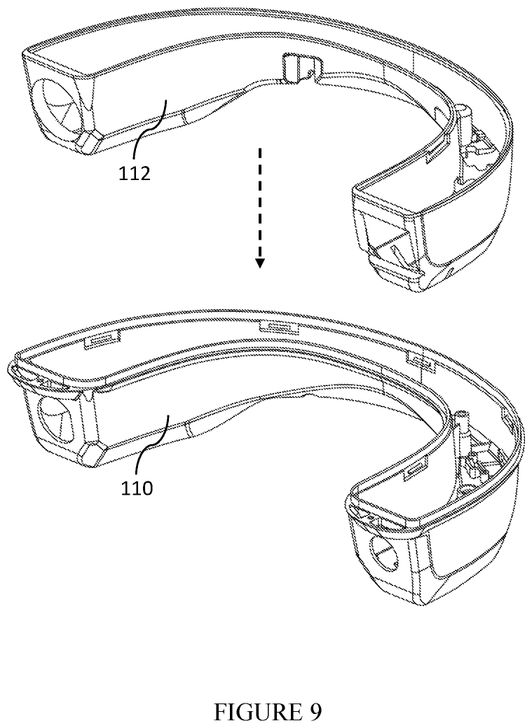

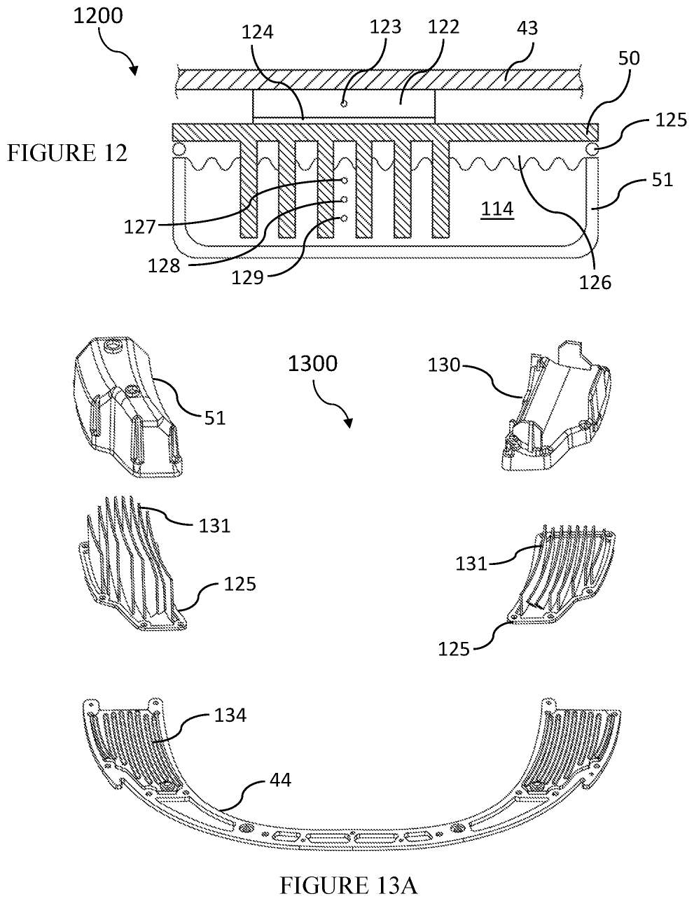

FIG. 5 is an exploded view of an internal core subassembly in an exemplary compute module, in accordance with one or more embodiments. View 500 shows an exploded view of internal compute subassembly 41, which may include many or all of the active electronic components of compute module 12, including antennas 42 and 46-49, main printed circuit board assembly (PCBA) 43, heat spreader and stiffener 44, antenna support 45, heat sink cores 50 and 52, heat sink shells 51 and 53, and battery module 54. All like-numbered elements in FIG. 5 are the same or similar to their corresponding elements in other figures. The internal core subassembly 41 may be built and tested during production prior to assembling into a compute module exterior housing (e.g., compute module exterior housing 56 in FIGS. 9 and 12). In some examples, compute module 12 may include a sensor unit for reading an identification (ID) tag (e.g., RFID tag, NFC tag, QR code, and other unique tags) provided on a compute module attachment 15. For example, antenna 42 may comprise an RFID antenna, as shown relative to main PCBA 43. In other examples, a camera or other type of reader may be provided instead of, or in addition to, antenna 42. In some examples, the ID tag may enable configuration and/or customization of a helmet mounted navigation and communications system to a given helmet or a user (e.g., to a user's assigned helmet). In other examples, the ID tag may enable collection of data associated with a given helmet or a user of the given helmet.

Main PCBA 43 may be shaped to wrap around a back portion of a user's head and under a brim of a helmet (e.g., helmet 16). Heat spreader and stiffener 44 may be configured to provide stiffness and support to compute module internal core assembly 41 generally, and to main PCBA 43 in particular, for example, to prevent flexing main PCBA 43 during manufacturing handling or use. As shown, main PCBA 43 may be shaped to have a thin width in the middle to correspond to the shape of other portions of compute module 12 (e.g., compute module exterior housing 56 in FIGS. 9 and 12). Heat spreader and stiffener 44 also may be configured to allow electronic elements on either end of main PCBA 43 to share heat, and thereby not overheat. Heat spreader and stiffener 44 also may provide a bridge between heat from main PCBA 43 and heat sinks below (e.g., a right heat sink comprising heat sink core 50 and heat sink shell 51 and a left heat sink comprising heat sink core 52 and heat sink shell 53). Heat sink cores 50 and 52, and heat sink shells 51 and 53, may be filled with phase change material (e.g., paraffin wax, other hydrocarbons, salt hydrate solutions, and the like) to provide thermal energy storage. For example, phase change material contained in the left and right heat sinks may be configured to phase change from a solid to a liquid, thereby storing heat dissipated from electronic components of compute module 12. High heat generating electronic components on main PCBA 43 may be placed on the wider ends of main PCBA 43 that correspond to the areas above the right and left heat sinks, thereby allowing heat dissipated from said electronic components to be conducted into the left and right heat sinks. Such placement increases compute module 12's ability to conduct heat from the electronics to the left and right heat sinks while minimizing and balancing the mass of compute module 12. For example, two or more heat sinks (e.g., left and right) may be distributed between the two larger regions of the housing in a manner that balances an overall mass of the compute module and reduces the moment of inertia. This enables compute module 12 to operate in extreme environments where it is unable to transfer heat to ambient surrounding air.

Battery (i.e., power) module 54 is an internal subassembly that may include a battery protection circuit PCBA, a battery cell, and a connector. In some examples, battery module 54 may not be serviceable. A battery module connector may connect to main PCBA 43. Antenna support 45 may be made of a plastic material and coupled to heat spreader and stiffener 44 (e.g., by screws). In some examples, antennas 46, 47, 48, and 49 may be attached to antenna support 45 with pressure sensitive adhesive. One or more of antennas 46-49 may be radio frequency antennas. Antennas 46-49 may be positioned on antenna support 45 along a back rear area of compute module 12 to provide antennas 46-49 with wide fields of view (e.g., pointing out and away from a back and/or side portion of a helmet and a user's head). As described herein internal core assembly 41 allows for a majority of electronic components, radio frequency and other antennas, heat sinks, and a battery module to be handled as a unit during production, assembly, and testing.

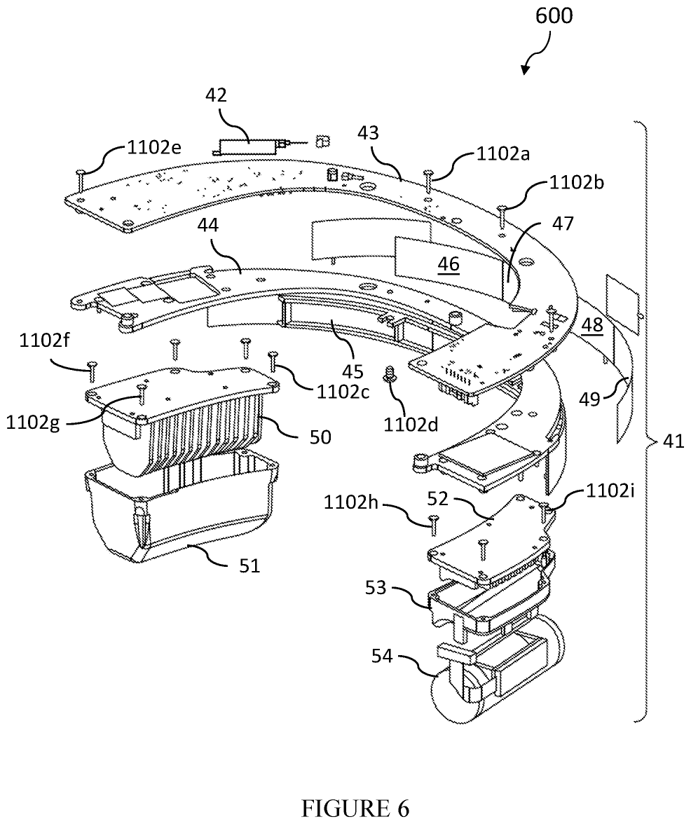

FIG. 6 is an exploded view of another internal core subassembly in an exemplary compute module, in accordance with one or more embodiments. All like-numbered elements in FIG. 6 are the same or similar to their corresponding elements in other figures. In addition to components described above, view 600 further shows various fasteners (e.g., fasteners 1102a-1102i) that may be used to attach heat sink cores 50 and 52 and heat sink shells 51 and 53 to each other, as well as to PCBA 43 and heat spreader and stiffener 44. In other examples, more or fewer fasteners may be used to attach components of the internal core subassembly. Other types of fasteners and means of coupling electronic, housing, and thermal protection components also may be used.

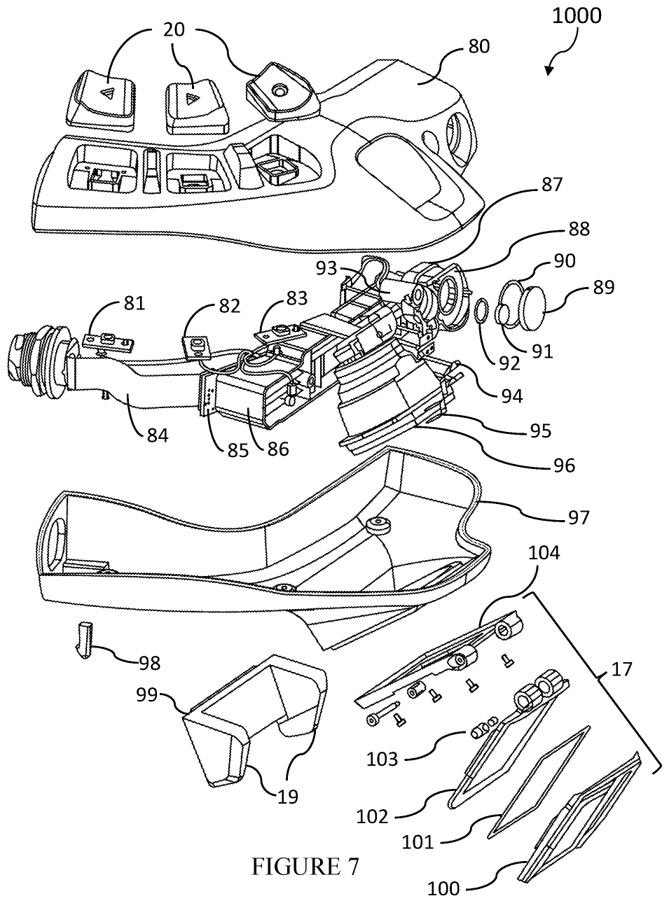

FIG. 7 is an exploded view of an exemplary vision module, in accordance with one or more embodiments. All like-numbered elements in FIG. 7 are the same or similar to their corresponding elements in other figures. Exploded view 1000 shows an example of vision module 11 that includes HUD combiner subassembly 17 and user control button(s) 20, as well as a top housing 80, bottom housing 97, user control button PCBAs 81-83, flexible (i.e., flex) cable 84, vision module main PCBA 85, vision module heat sink 86, thermal camera rear mount 87, thermal camera 88, glass 89, retaining ring 90, laser glass 91 (covering laser aperture 74), laser aperture ring 92, laser 93, flex circuit 94, hall effect sensor 95, and optic subassembly 96. All like-numbered elements in FIG. 7 are the same or similar to their corresponding elements in other figures. In some examples, top housing 80 and bottom housing 97 (collectively, “vision module housing”) may be plastic injection molded to form a hard plastic shell of impact resistant plastic having properties for withstanding extreme environments (e.g., high heat deflection temperature material properties). In some examples, top housing 80 and bottom housing 97 may be sealed together so that the vision module housing provides ingress protection against water and debris. In some examples, vision module bottom housing 97 may include features for fastening together with vision module top housing 80, as well as a window for a display image to exit. Bottom housing 97 may include sealing grooves around its perimeter to allow for a form-in-place gasket, adhesive, or separate sealing part.

User control button(s) 20 may comprise actuator switches configured to actuate user control button PCBAs 81-83. In an example, user control button PCBAs 81-83 each may include an electro-mechanical switch on a top surface and a small 230 connector on a bottom surface. A wire harness (not shown) may connect the 230 connector to vision module main PCBA 85. Cable connection interface 26 may be ingress protected and may make electrical connection(s) with PCBA 85 using flex cable 84.

Vision module 11 also may include heat sink 86 configured to store heat dissipated from electronic components of vision module 11. In some examples, heat sink 86 may comprise a heat sink core and a heat sink shell, and may be filled with phase change material (e.g., paraffin wax, other hydrocarbons, salt hydrate solutions, and the like) to provide thermal energy storage. For example, phase change material contained in heat sink 86 may be configured to phase change from a solid to a liquid, thereby storing heat dissipated from electronic components of vision module 11. This enables vision module 11 to operate in extreme environments where it is unable to transfer heat to ambient surrounding air.

Thermal camera rear mount 87 may couple to thermal camera 88, for example, positioned around thermal camera 88 to hold it in place. In some examples, thermal camera rear mount 87 may comprise an elastomeric material to provide shock absorption. Glass 89 may be made of germanium glass, including a window through which thermal camera 88 may see through (e.g., receive light and have a view of tracking a user's line of sight). Glass 89 may be retained (e.g., held in place) by retaining ring 90. Retaining ring 90 may be bonded into position in vision module top housing 80. Laser glass 91 also may be positioned (e.g., attached, glued, or otherwise secured) in laser aperture ring 92 in vision module top housing 80 and configured to cover laser aperture 74. Laser 93 (e.g., a pointing laser) may be placed such that it points out of laser aperture ring 92. Flex circuit 94 may connect vision module PCBA 85 to hall effect sensor 95 and optic subassembly 96. Hall effect sensor 95 may be positioned at the end of an ambient light sensor with flex circuit 94 positioned to sense if HUD combiner subassembly 17 is in an open or closed position. Optic subassembly 96 may comprise two or more functional subassemblies, including a display subassembly having an LCOS display and light engine and a lens subassembly comprising one or more lenses.

In some examples, vision module 11 includes retention latch 98 configured to interface with vision module attachment 14 (e.g., latch mechanism 24 thereon). In this example, bumper(s) 19, as described above, may be part of a front bumper 99.

Also shown in exploded view 1000 are components of HUD combiner subassembly 17, including a world facing combiner shell 100, combiner glass 101, user facing combiner shell 102, and a combiner mount frame 104. In an example, combiner glass 101 may be adhesively bonded to world facing combiner shell 100 along its perimeter edge. World facing combiner shell 100 and user facing combiner shell 102 may be bonded together along their perimeter edges to trap combiner glass 101 in a sealed volume. World facing combiner shell 100 and user facing combiner shell 102 may be coated with a hydrophilic material to minimize fogging and optical distortion from moisture (e.g., by increasing water sheeting). World facing combiner shell 100, combiner glass 100, and user facing combiner shell 102, may be assembled with combiner mount frame 104, which may comprise a combiner pivot mechanism 103 (e.g., same or similar to axis of rotation and clutch mechanism 25). Combiner pivot mechanism 103 may be configured to allow a combiner display to hold an open position and allow for user adjustment to one or more pivot angles for improved viewing. In the example shown, the replaceable HUD combiner subassembly 17 may be attached and removed from vision module 11 using a plurality of screws (e.g., screwed through combiner frame 104).

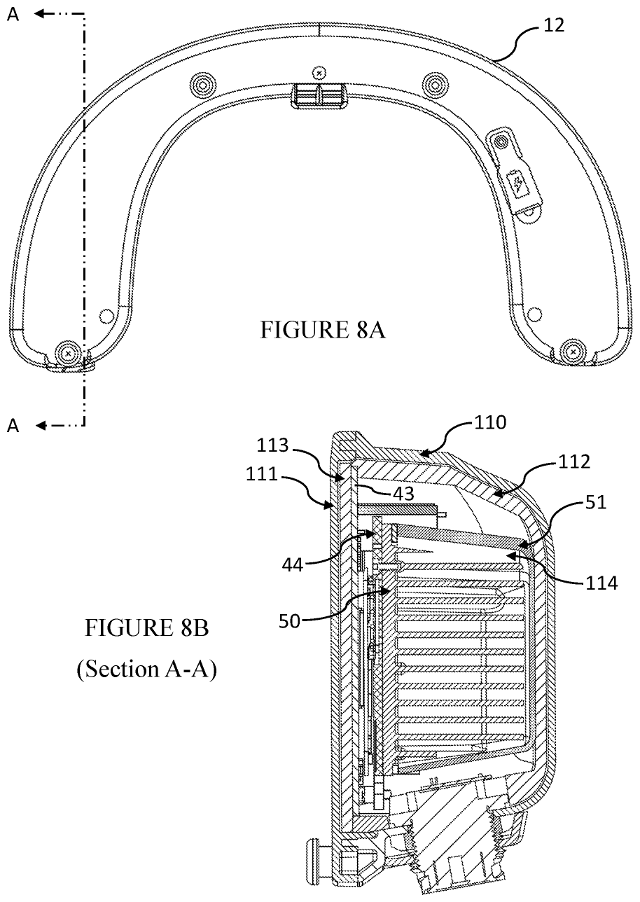

FIGS. 8A-8B are a top and cross-section views of an exemplary compute module, in accordance with one or more embodiments. All like-numbered elements in FIGS. 8A-8B are the same or similar to their corresponding elements in other figures. FIG. 8A shows a top view of compute module 12, illustrating the location of cross-section A-A. FIG. 8B shows cross-section A-A detail. In some examples, compute module 12 includes compute module top housing 111, compute module bottom housing 110, PCBA 43, heat spreader and stiffener 44, heat sink core 50, heat sink shell 51, bottom housing insulation 112, top housing insulation 113, and volume 114. Some components of compute module 12 (e.g., compute module top housing 111, compute module bottom housing 110, bottom housing insulation 112, top housing insulation 113, and the like) may be configured to isolate and insulate internal electronics, and to reject heat, from external (i.e., outside, environmental) sources. Some components of compute module 12 (e.g., heat sink core 50, heat sink shell 51, and the like) may be configured to collect heat generated by internal electronics and store it in heat sink phase change material (e.g., in volume 114). Electronic heat dissipating components may be grouped at each end of the compute module PCBA 43. Heat sinks (e.g., comprising heat sink core 50 and heat sink shell 51) may be installed at each end of PCBA 43 with a volume of phase change material (e.g., volume 114) tuned to an amount of heat coming from nearby (e.g., adjacent) group of electronic components (e.g., on the respective end of PCBA 43).

In some examples, compute module top housing 111 and compute module bottom housing 112 may be coated with reflective and/or ceramic coatings to reflect radiant heat, thereby keeping the module cooler. In some examples, compute module bottom housing insulation 112 and top housing insulation 113 may comprise a foam or foam-like material having very low thermal conductivity. As shown, foam that can be molded to the net shape desired for production, or nearly the same net shape, may be used. In some examples, insulation 112 and 113 may comprise a material that can be molded into uniform cross sections sizes and shapes. In other examples, insulation 112 and 113 may comprise a material that can be molded into varying sizes and shapes (e.g., varying wall thickness) such that insulation designs can fill available system voids (e.g., volume 114 and other volume shapes and sizes). For example, volume 114 created by a void between heat sink core 50 and heat sink shell 51 may comprise phase change material for energy (e.g., heat) storage. In some examples, heat sink shell 51 may be fabricated out of glass (e.g., glass fiber) filled engineering injection molding resin for increased strength and higher overall operating temperature.

FIG. 9 is an exploded view of an exemplary compute module, in accordance with one or more embodiments. All like-numbered elements in FIG. 9 are the same or similar to their corresponding elements in other figures. In some examples, an outer surface of bottom insulation 112 may be smooth and slightly offset from an inside surface of bottom housing 110 to allow for ease of assembly and proper fit.

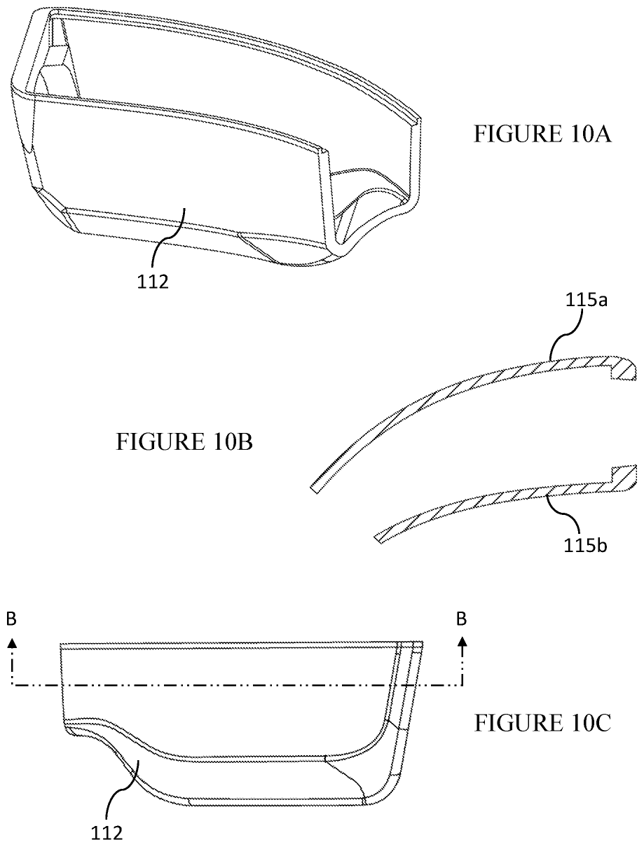

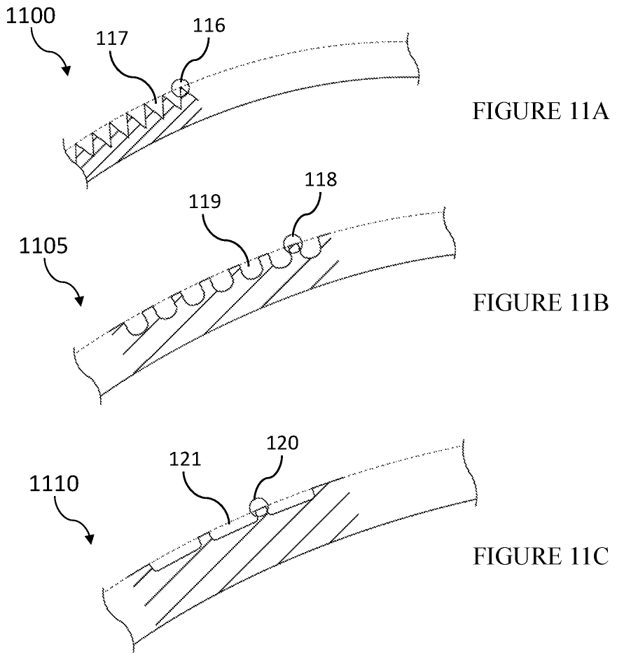

FIGS. 10A-10C are isolated cut, cross-section, and side views, respectively, of an exemplary compute module bottom insulation, in accordance with one or more embodiments. All like-numbered elements in FIGS. 10A-10C are the same or similar to their corresponding elements in other figures. In some examples, insulation 112 may comprise a uniform nominal wall thickness and smooth outer surface. The cross-section view in FIG. 10B and side view in FIG. 10C are truncated for illustrative purposes only. Outer surfaces 115a-115b may be slightly offset from an inner surface of compute module bottom housing 110. In other examples, insulation 112 may be designed with a different shape, size, and thickness to optimize heat transfer paths with least thermal resistance for a given system. For example, additional features (e.g., grooves of various shapes, as shown in FIGS. 11A-11C) may be formed on outer surfaces 115a-115b. Adding grooves of various shapes to outer surfaces 115a-115b may force external heat to take a more convoluted path, and less surface area of outer surfaces 115a-115b may touch an inner surface of a housing (e.g., compute module bottom housing 110, compute module top housing 111, vision module top housing 80, vision module bottom housing 97).

FIGS. 11A-11C are top views of an exemplary outer surface of a compute module insulation, in accordance with one or more embodiments. All like-numbered elements in FIGS. 11A-11C are the same or similar to their corresponding elements in other figures. FIG. 11A illustrates a sawtooth pattern comprising peaks 116 and void regions 117 (i.e., air channels) resulting from a plurality of grooves. FIG. 11B illustrates a rounded groove pattern comprising peaks 118 and void regions 119 (i.e., air channels). FIG. 11C illustrates a widened groove pattern comprising peaks 120 and larger void regions 121 (i.e., air channels). Peaks 116, 118 and 120 may be small (e.g., narrow, sharp, otherwise having little surface area) to reduce contact surface area with an inner surface of a housing (e.g., compute module bottom housing 110, compute module top housing 111, vision module top housing 80, vision module bottom housing 97). In some examples, peaks 116, 118 and 120 also may be modeled for a slight interference fit with an inner surface of a housing to allow for a bit of compression. Void regions 117, 119 and 121 may be created by grooves of varying shapes and sizes. In some examples, void regions 117, 119 and 121 may comprise air through which heat may pass. A void region may have a narrow cross-section (e.g., void region 117), a round cross-section (e.g., void region 119), a wide cross-section (e.g., void region 121), and other shapes and sizes. These groove designs may cause an inner surface of a housing to pass heat through convection into small air channels created by grooves, which enhances insulation performance. The grooved method shown here may be used in the thermal protection design of one or both of compute module 12 and vision module 11.

FIG. 12 is a cross-section view of an exemplary temperature sensing system, in accordance with one or more embodiments. All like-numbered elements in FIG. 12 are the same or similar to their corresponding elements in other figures. View 1200 shows various components of a compute module 12, including PCBA 43 and a representative high power dissipation electronic component 122 comprising a thermal sensor 123. In some examples, thermal sensor 123 may be a built-in component of electronic component 122. Thermal sensor 123 may be read by, or otherwise provide heat and temperature data to, a system software implemented by compute module 12. In some examples, electronic component 122 may have a thermal interface to heat sink core 50 through thermal interface material 124. There may be a formed or form-in-place sealing gasket 125, for example, between heat sink core 50 and heat sink shell 51, thereby sealing in a void region 126 containing air. Gasket 125 may be configured to create a seal around an edge of heat sink shell 51. View 1200 also shows additional thermal sensors 127, 128 and 129, which also may be read by, or otherwise provide heat and temperature data to, a system software implemented by compute module 12. As shown, thermal sensors 127-129 may be placed in a part of volume 114 central to the footprint of a heat-producing component (e.g., electronic component 122). Volume 114 may comprise a phase change material, and thermal sensors 127-129 may be submerged (i.e., suspended) in said phase change material. Volume 114 may be filled with an amount of phase change material that allows the phase change material may expand within volume 114 when heated (e.g., paraffin typically expands 8-12% when heat is absorbed). For example, phase change material may expand into void region 126. Gasket 125 may be configured to create a seal around heat sink shell 51 to seal the phase change inside the system (e.g., contain the phase change material within volume 114 and void region 126).

In some examples, a temperature of the system may be evaluated by a software program using data from thermal sensors 127-129 (e.g., when the system is turned on, periodically after the system is turned on, ad hoc using user control buttons, according to a schedule, etc.). When the temperature of the system goes above a phase change temperature of the phase change material in volume 114, the system (e.g., the software program) may determine how much additional thermal reserve remains available and an amount of heat energy that the system can continue to absorb. Built-in thermal sensors (e.g., thermal sensor 123) may be used as a second check. With the thermal status of the system fully characterized, the system (e.g., the software program) may determine a thermal resistance between thermal sensor 123 and heat sink core 50 in situ, and the thermal resistance used to calculate remaining thermal reserve at runtime.

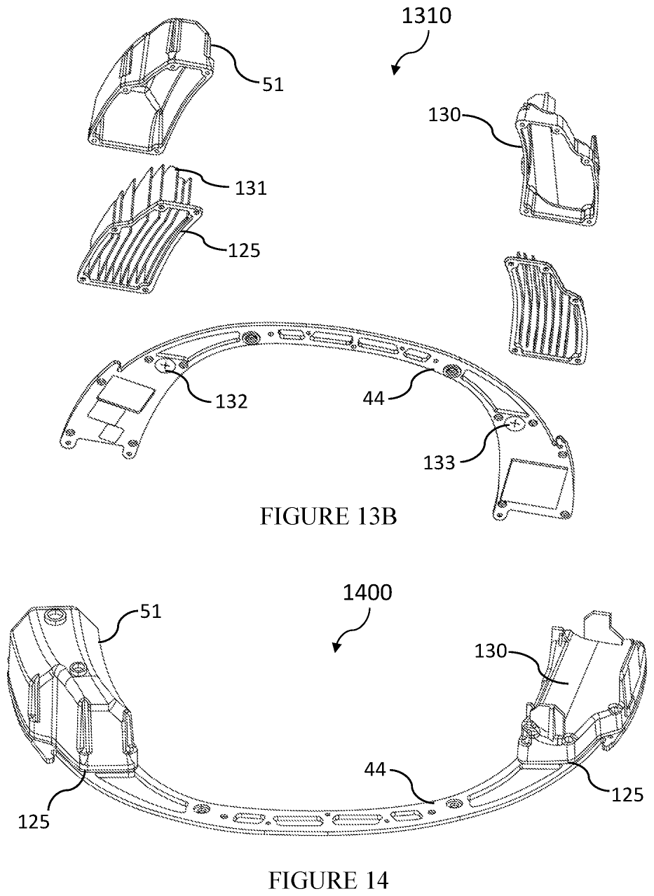

FIGS. 13A-13B are exploded views of an exemplary compute module heat sink and stiffener, in accordance with one or more embodiments. All like-numbered elements in FIGS. 13A-13B are the same or similar to their corresponding elements in other figures. In view 1300, an interface between heat sink cores 50 and 52 in the compute module and stiffener 44 is simplified and lightened. This also results in a reduction of materials (e.g., aluminum) necessary in assembly, thereby reducing the system weight while improving thermal protection performance. View 1300 shows a stiffener 44 comprising lightning hole features to reduce weight and slightly thicker regions on the ends to allow for grooves 134 to be machined directly into a thin aluminum plate. This embodiment uses fins 131 in the heat sink which are bonded (e.g., glued) with thermally conductive adhesive in grooves 134. In some examples, heat sink shells 51 and 130 may be used to contain phase change material inside. Heat sink shells 51 and 130 also may be fabricated out of glass (e.g., glass fiber) filled engineering injection molding resin for increased strength and higher overall operating temperature. Formed or form-in-place gaskets 125 may provide a seal between heat sink shells 51 and 130 and stiffener 44.

In some examples, one or more parts (e.g., fins 131, stiffener 44, heat sink shells 51 and 130) may be manufactured in separate (i.e., individual) pieces for ease of manufacturing. Fins 131 may comprise long, thin fins, as shown, for improved thermal performance. Fins 131 may comprise one, or a combination, of thin aluminum, thin copper, thin graphite sheets, and other suitable materials. Stiffener may be made (e.g., formed, cut, otherwise manufactured) from a thin plate. Fins 131 may be used on both ends of PCBA 43.

In FIG. 13B, view 1310 further shows fasteners 132-133 with o-rings. In some examples, openings for fasteners 132-133 may be used to fill heat sink shells 51 and 130 with phase change material.

FIG. 14 is perspective view of an exemplary compute module heat sink and stiffener as assembled, in accordance with one or more embodiments. All like-numbered elements in FIG. 14 are the same or similar to their corresponding elements in other figures. View 1400 shows heat sink shells 51 and 130 assembled onto stiffener 44 and sealed with gaskets 125.

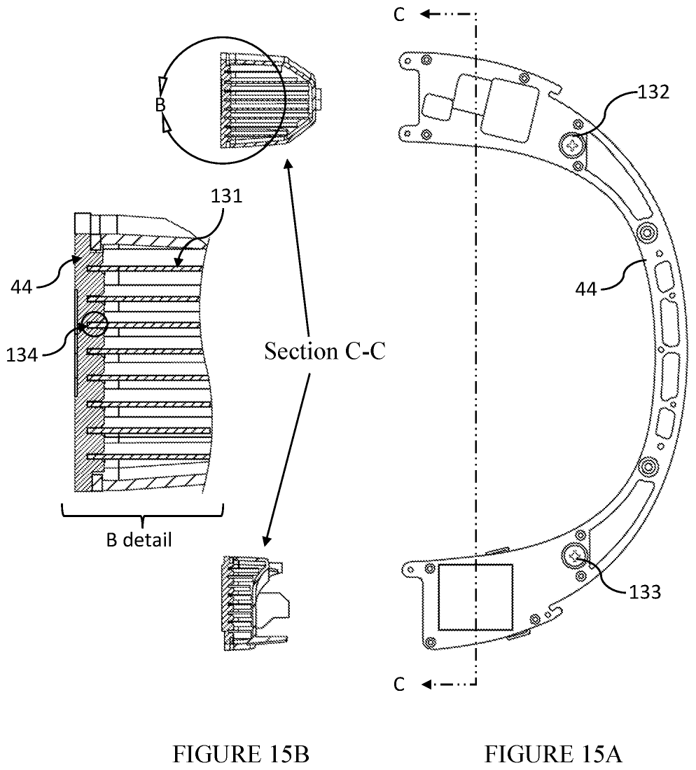

FIGS. 15A-15B are top and cross-section views, respectively, of an exemplary compute module heat sink, in accordance with one or more embodiments. All like-numbered elements in FIGS. 15A-15B are the same or similar to their corresponding elements in other figures. Fasteners 132-133 are shown on stiffener 44. As described herein, fasteners 132-133 may be removed to expose openings (i.e., holes) through which phase change material may be input (e.g., poured or otherwise added) into a volume (e.g., volume 114). Fasteners 132-133 may include an o-ring to provide a proper seal (e.g., to contain the phase change material when it is in a liquid state). In some examples, stiffener 44 may be locally thicker in a region where fins 131 are bonded. Thermally conductive adhesive may be placed in a groove 134. In some examples, fins 131 may be assembled and fixed while said thermally conductive adhesive is curing.

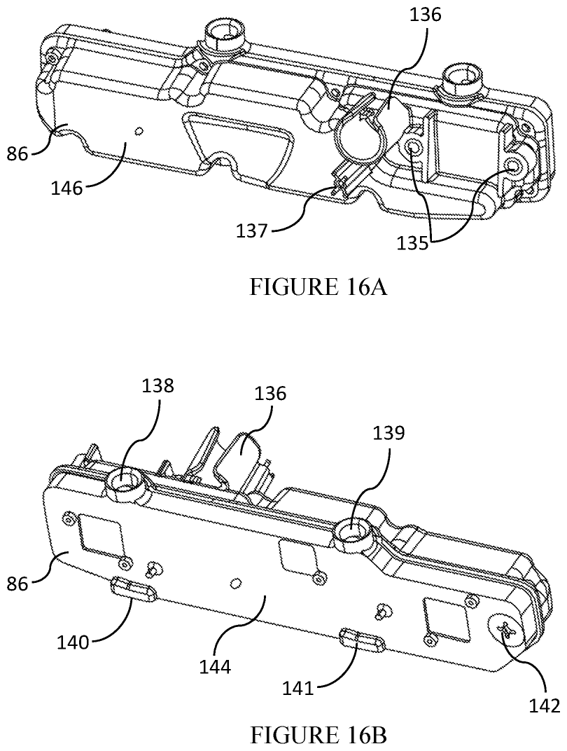

FIGS. 16A-16B are perspective front and back views, respectively, of a vision module heat sink, in accordance with one or more embodiments. All like-numbered elements in FIGS. 16A-16B are the same or similar to their corresponding elements in other figures. As shown, assembled vision module heat sink 86 may comprise fastener bosses 135, pointing laser 136, mounting bosses 137, top mount points 138-139, bottom mount points 140-141, sealing fastener 142, vision module heat sink core 144, and vision module heat sink shell 146. In some examples, vision module heat sink shell 146 may be fabricated out of glass (e.g., glass fiber) filled engineering injection molding resin for increased strength and higher overall operating temperature. Since this is a molded part, adding additional features is relatively cost-effective. To reduce weight, enable a more compact vision module overall design, and to reduce part count and complexity, the vision module heat sink shell 146 may include mounting reference features and fastener bosses 135 for a thermal camera or other parts, as well as mounting features for a pointing laser 136 and mounting bosses 137 to hold items like an ambient light sensor. The vision module heat sink 86 may be configured to capture internally generated heat from electronic component heat dissipation using a metal vision module heat sink core 144. Adding mounters for electronic accessory parts yields a more compact design.

FIG. 16B shows sealing fastener 142, which may be removed to facilitate filling the heat sink with liquid phase change material as described herein. Design elements to isolate the vision module heat sink 86 and its attached parts and electronics from vision module top housing 80 and bottom housing 97 (e.g., shown in FIG. 7) are shown as top mount points 138-139 and bottom mount points 140-141. Mounting and constraining the vision module heat sink and attached parts with these strategic mount points creates only small thermally conductive physical interfaces for outside ambient environment heat to be transferred to the internal parts and electronics. In some examples, vision module top housing 80 and vision module bottom housing 97 (e.g., shown in FIG. 7) may be coated with reflective and/or ceramic coatings to reflect radiant heat, thereby keeping the vision module cooler overall.

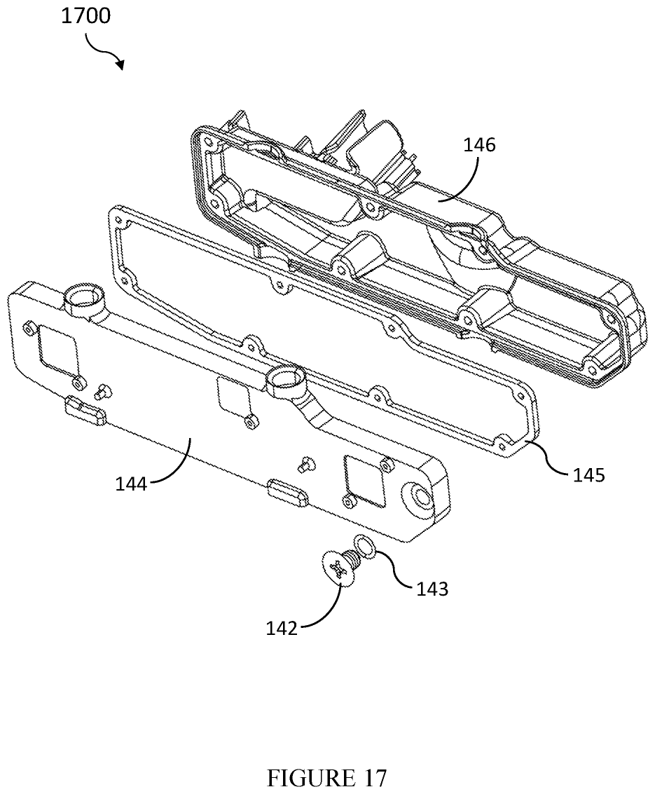

FIG. 17 is an exploded view of a vision module heat sink, in accordance with one or more embodiments. All like-numbered elements in FIG. 17 are the same or similar to their corresponding elements in other figures. View 1700 shows sealing fastener 142 and sealing o-ring 143. As described herein, sealing fastener 142 and o-ring 143 may be removed to expose an opening that may be used as a filling port for phase change material. In some examples, vision module heat sink core 144 may be constructed of high thermal conductivity aluminum. A formed or a form-in-place gasket 145 is shown to seal in the liquid phase change material. An injection molded engineering resin with glass fill heat sink shell 146 may comprise internal features and mounting points as shown.

A person of ordinary skill in the art will recognize that the systems described herein may be implemented on various types of protective headgear used by emergency response personnel and critical workers for any type of emergency response, military, law enforcement, public safety, and other similar efforts and missions.

While specific examples have been provided above, it is understood that the present invention can be applied with a wide variety of inputs, thresholds, ranges, and other factors, depending on the application. For example, the time frames, rates, ratios, and ranges provided above are illustrative, but one of ordinary skill in the art would understand that these time frames and ranges may be varied or even be dynamic and variable, depending on the implementation.

As those skilled in the art will understand a number of variations may be made in the disclosed embodiments, all without departing from the scope of the invention, which is defined solely by the appended claims. It should be noted that although the features and elements are described in particular combinations, each feature or element can be used alone without other features and elements or in various combinations with or without other features and elements. The methods or flow charts provided may be implemented in a computer program, software, or firmware tangibly embodied in a computer-readable storage medium for execution by a general-purpose computer or processor.

Examples of computer-readable storage mediums include a read only memory (ROM), random-access memory (RAM), a register, cache memory, semiconductor memory devices, magnetic media such as internal hard disks and removable disks, magneto-optical media, and optical media such as CD-ROM disks.

Suitable processors include, by way of example, a general-purpose processor, a special purpose processor, a conventional processor, a digital signal processor (DSP), a plurality of microprocessors, one or more microprocessors in association with a DSP core, a controller, a microcontroller, Application Specific Integrated Circuits (ASICs), Field Programmable Gate Arrays (FPGAs) circuits, any other type of integrated circuit (IC), a state machine, or any combination of thereof.

What is claimed is:

1. A thermal protection system for a helmet mounted navigation and communication system, comprising:
a vision module heat sink configured to store heat dissipated from one or more electronic components of a vision module;
a compute module heat sink configured to store heat dissipated from one or more electronic components of a compute module; and
a compute module heat spreader coupled to the compute module heat sink and an electronic component of the compute module;
wherein each of the vision module heat sink and the compute module heat sink comprises a heat sink core at least partially filled with a phase change material.

2. The system of claim 1, wherein the compute module comprises a compute module housing and a printed circuit board assembly (PCBA).

3. The system of claim 2, wherein the compute module housing and the PCBA each comprise two larger regions and a smaller region between the two larger regions.

4. The system of claim 3, wherein the compute module heat sink comprises a pair of compute module heat sinks distributed among the two larger regions of the compute module housing.

5. The system of claim 3, wherein the one or more electronic components of the compute module are placed on one or both of the two larger regions of the PCBA near at least one of the pari of compute module heat sinks.

6. The system of claim 1, wherein the compute module is coupled to a user's helmet such that it sits under a back brim of the user's helmet and wraps around a back portion of a user's head.

7. The system of claim 1, wherein the vision module comprises a vision module housing and the compute module comprises a compute module housing, one or both of the vision module housing and the compute module housing comprising a reflective coating.

8. The system of claim 1, further comprising one or both of a compute module insulation and a vision module insulation.

9. The system of claim 8, wherein one or both the compute module insulation and the vision module insulation comprise a foam or foam-like material having a low thermal conductivity.

10. The system of claim 8, wherein an outer surface of one or both of the compute module insulation and the vision module insulation comprises a plurality of grooves.

11. The system of claim 8, wherein an outer surface of one or both of the compute module insulation and the vision module insulation comprises a smooth surface.

12. The system of claim 1, wherein one or both of the vision module heat sink and the compute module heat sink comprises a heat sink shell comprised of a material having a high operating temperature.

13. The system of claim 12, wherein the material is glass filled engineering injection molding resin.

14. The system of claim 12, further comprising a gasket configured to create a seal around an edge of the heat sink shell, the gasket configured to seal the phase change material in a volume between the heat sink shell and the heat sink core.

15. The system of claim 1, wherein one or both of the vision module heat sink and the compute module heat sink comprises a volume of the phase change material, the volume tuned to an amount of heat dissipating from the one or more electronic components of the vision module and the one or more electronic components of the compute module, respectively.

16. The system of claim 1, wherein the compute module heat sink comprises a plurality of fins bonded to the heat spreader, the heat spreader further configured to provide stiffness and support to the one or more electronic components of a compute module.

17. The system of claim 16, wherein the heat spreader comprises a sealing fastener, wherein removal of the sealing fastener exposes an opening configured for adding the phase change material to an internal volume of the heat sink.

18. The system of claim 1, wherein the vision module heat sink comprises a mounting feature for one or more components of the vision module.

19. The system of claim 18, wherein the mounting feature comprises a mounting boss and a fastener.

20. The system of claim 18, wherein the mounting feature isolates the vision module heat sink and reduces a thermally conductive physical interface between the one or more electronic components of the vision module and an outside environment.

21. The system of claim 1, wherein the heat sink core comprises aluminum.

22. The system of claim 1, further comprising a cable housing comprising heat resistant material configured to protect a cable from exterior heat.

23. The system of claim 1, further comprising one or more thermal sensors submerged in the phase change material, the one or more thermal sensors configured to provide data being used to determine a remaining thermal reserve.
